(19) United States
(12) Patent Application Publication
(10) Pub. No.: US 2021/0066156 A1
(43) Pub. Date: Mar. 4, 2021

(54) STACKED STRUCTURE AND METHOD FOR MANUFACTURING THE SAME

(71) Applicant: Advanced Semiconductor Engineering, Inc., Kaohsiung (TW)

(72) Inventor: Wen Hung HUANG, Kaohsiung (TW)

(73) Assignee: Advanced Semiconductor Engineering, Inc., Kaohsiung (TW)

(21) Appl. No.: 16/557,992

(22) Filed: Aug. 30, 2019

(51) Int. Cl. H01L 23/373; H01L 23/66; H01L 23/522

(52) U.S. Cl. CPC H01L 23/373; H01L 2223/6677; H01L 23/5226; H01L 23/66

(57) ABSTRACT

A stacked structure includes a lower structure, an upper structure and a buffer layer. The lower structure includes at least one lower dielectric layer and at least one lower metal layer in contact with the lower dielectric layer. The upper structure includes at least one upper dielectric layer and at least one upper metal layer in contact with the upper dielectric layer. The buffer layer is interposed between the lower structure and the upper structure. A coefficient of thermal expansion (CTE) of the buffer layer is between a coefficient of thermal expansion (CTE) of the lower structure and a coefficient of thermal expansion (CTE) of the upper structure.

### BACKGROUND

### 1. Field of the Disclosure

The present disclosure relates to a stacked structure and a manufacturing method, and to a stacked structure including a buffer layer and a method for manufacturing the stacked structure.

### 2. Description of the Related Art

A stacked semiconductor device package may include two stacked structures. The stacked structures are formed on both sides of a core substrate. Then, a semiconductor die is attached to one of the stacked structures. The dielectric layers of the two stacked structures may have the same material. Thus, a thickness of the dielectric layer may not be reduced efficiently due to the consideration of its material property such as dielectric constant (Dk). Accordingly, the total thickness of the stacked semiconductor device package may not be reduced efficiently. In addition, warpage to the stacked semiconductor device package is an issue.

### SUMMARY

In some embodiments, a stacked structure includes a lower structure, an upper structure and a buffer layer. The lower structure includes at least one lower dielectric layer and at least one lower metal layer in contact with the lower dielectric layer. The upper structure includes at least one upper dielectric layer and at least one upper metal layer in contact with the upper dielectric layer. The buffer layer is interposed between the lower structure and the upper structure. A coefficient of thermal expansion (CTE) of the buffer layer is between a coefficient of thermal expansion (CTE) of the lower structure and a coefficient of thermal expansion (CTE) of the upper structure.

In some embodiments, a stacked structure includes a routing structure, an antenna structure and a buffer layer. The routing structure includes at least one dielectric layer and at least one metal layer in contact with the dielectric layer. The antenna structure includes at least one dielectric layer and at least one metal layer in contact with the dielectric layer. The buffer layer has a first surface in contact with the routing structure and a second surface opposite to the first surface and in contact with the antenna structure. A surface roughness of the first surface is greater than a surface roughness of the second surface.

In some embodiments, a method for manufacturing a stacked structure includes (a) forming a lower structure, wherein the lower structure includes at least one lower dielectric layer and at least one lower metal layer in contact with the lower dielectric layer; (b) forming a buffer layer on the top surface of the lower structure, wherein the buffer layer has a first surface and a second surface opposite to the first surface, the first surface of the buffer layer contacts the top surface of the lower structure, and a surface roughness of the first surface of the buffer layer is different from a surface roughness of the second surface of the buffer layer; and (c) forming an upper structure on the buffer layer, wherein the upper structure includes at least one upper dielectric layer and at least one upper metal layer in contact with the upper dielectric layer.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of a stacked structure according to some embodiments of the present disclosure.

FIG. 2 illustrates a cross-sectional view of a stacked structure according to some embodiments of the present disclosure.

FIG. 3 illustrates a cross-sectional view of a stacked structure according to some embodiments of the present disclosure.

FIG. 4 illustrates a cross-sectional view of a stacked structure according to some embodiments of the present disclosure.

FIG. 5 illustrates a cross-sectional view of a package structure according to some embodiments of the present disclosure.

FIG. 6 illustrates a cross-sectional view of a package structure according to some embodiments of the present disclosure.

FIG. 7 illustrates a cross-sectional view of a package structure according to some embodiments of the present disclosure.

FIG. 8 illustrates one or more stages of an example of a method for manufacturing a stacked structure according to some embodiments of the present disclosure.

FIG. 9 illustrates one or more stages of an example of a method for manufacturing a stacked structure according to some embodiments of the present disclosure.

FIG. 10 illustrates one or more stages of an example of a method for manufacturing a stacked structure according to some embodiments of the present disclosure.

FIG. 11 illustrates one or more stages of an example of a method for manufacturing a stacked structure according to some embodiments of the present disclosure.

FIG. 12 illustrates one or more stages of an example of a method for manufacturing a stacked structure according to some embodiments of the present disclosure.

FIG. 13 illustrates one or more stages of an example of a method for manufacturing a stacked structure according to some embodiments of the present disclosure.

FIG. 14 illustrates one or more stages of an example of a method for manufacturing a stacked structure according to some embodiments of the present disclosure.

FIG. 15 illustrates one or more stages of an example of a method for manufacturing a stacked structure according to some embodiments of the present disclosure.

FIG. 16 illustrates one or more stages of an example of a method for manufacturing a stacked structure according to some embodiments of the present disclosure.

FIG. 17 illustrates one or more stages of an example of a method for manufacturing a stacked structure according to some embodiments of the present disclosure.

FIG. 18 illustrates one or more stages of an example of a method for manufacturing a stacked structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

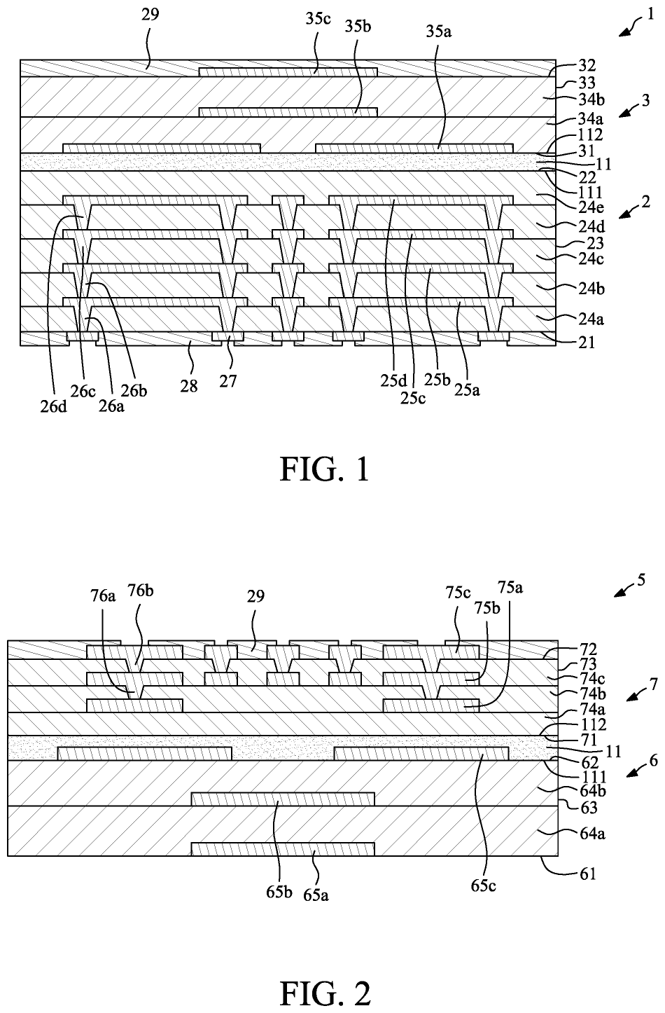

FIG. 1 illustrates a cross-sectional view of a stacked structure 1 according to some embodiments of the present disclosure. The stacked structure 1 includes a lower structure 2, an upper structure 3, a buffer layer 11, a lower circuit layer 27, a lower protection layer 28 and an upper protection layer 29.

The lower structure 2 may be a routing structure, and has a first surface (bottom surface) 21, a second surface (top surface) 22 opposite to the first surface 21 and a lateral side surface 23 extending between the first surface 21 and the second surface 22. The lower structure 2 may include at least one lower dielectric layer (including, for example, a first lower dielectric layer 24a, a second lower dielectric layer 24b, a third lower dielectric layer 24c, a fourth lower dielectric layer 24d and a fifth lower dielectric layer 24e), at least one lower metal layer (including, for example, a first lower metal layer 25a, a second lower metal layer 25b, a third lower metal layer 25c, a fourth lower metal layer 25d) in contact with or interposed between the lower dielectric layers 24a, 24b, 24c, 24d, 24e, and a plurality of lower vias (including, for example, a first lower via 26a, a second lower via 26b, a third lower via 26c and a fourth lower via 26d) embedded in the lower dielectric layers 24a, 24b, 24c, 24d.

In some embodiments, each of the lower dielectric layers (including, for example, the first lower dielectric layer 24a, the second lower dielectric layer 24b, the third lower dielectric layer 24c, the fourth lower dielectric layer 24d and the fifth lower dielectric layer 24e) may include, or be formed from, a photoresist layer, a passivation layer, a cured photo sensitive material, a cured photoimageable dielectric (PID) material such as epoxy, polypropylene (PP), or polyimide (PI) including photoinitiators, or a combination of two or more thereof. A dielectric constant (Dk) of each of the lower dielectric layers 24a, 24b, 24c, 24d, 24e may be 3.3 to 3.9. In some embodiments, each of the lower dielectric layers 24a, 24b, 24c, 24d, 24e may include fibers therein.

Each of the lower metal layers 25a, 25b, 25c, 25d includes a patterned circuit layer that may include a plurality of traces and a plurality of pads. The lower metal layers 25a, 25b, 25c, 25d are electrically connected to one another through the lower vias (including, for example, the first lower via 26a, the second lower via 26b, the third lower via 26c and the fourth lower via 26d). For example, the lower circuit layer 27 is disposed on the first surface 21 of the lower structure 2. The first lower metal layer 25a is disposed on the first lower dielectric layer 24a and electrically connected to the lower circuit layer 27 through the first lower via 26a. The second lower dielectric layer 24b is disposed on the first lower dielectric layer 24a to cover the first lower metal layer 25a. The second lower metal layer 25b is disposed on the second lower dielectric layer 24b and electrically connected to the first lower metal layer 25a through the second lower via 26b. The third lower dielectric layer 24c is disposed on the second lower dielectric layer 24b to cover the second lower metal layer 25b. The third lower metal layer 25c is disposed on the third lower dielectric layer 24c and electrically connected to the second lower metal layer 25b through the third lower via 26c. The fourth lower dielectric layer 24d is disposed on the third lower dielectric layer 24c to cover the third lower metal layer 25c. The fourth lower metal layer 25d is disposed on the fourth lower dielectric layer 24d and electrically connected to the third lower metal layer 25c through the fourth lower via 26d.

The buffer layer 11 is disposed on the lower structure 2, and is interposed between the lower structure 2 and the upper structure 3. The buffer layer 11 has a first surface (bottom surface) 111 and a second surface (top surface) 112 opposite to the first surface 111. The first surface 111 of the buffer layer 11 contacts the second surface 22 of the lower structure 2. A coefficient of thermal expansion (CTE) of the buffer layer 11 is between a coefficient of thermal expansion (CTE) of the lower structure 2 and a coefficient of thermal expansion (CTE) of the upper structure 3. In some embodiments, the CTE of the buffer layer 11 is greater than the CTE of the lower structure 2, and is less than the CTE of the upper structure 3. Alternatively, the CTE of the dielectric layer (including, for example, a first upper dielectric layer 34a and a second upper dielectric layer 34b) of the antenna structure (e.g., the upper structure 3) is greater than the CTE of the buffer layer 11, and the CTE of the buffer layer 11 is greater than the CTE of the dielectric layer (e.g., the lower dielectric layers 24a, 24b, 24c, 24d, 24e) of the routing structure (e.g., the lower structure 2). For example, the CTE of the lower structure 2 may be 9 ppm/° C. to 15 ppm/° C., the CTE of the buffer layer 11 may be 20 ppm/° C. to 50 ppm/° C., and the CTE of the upper structure 3 may be 90 ppm/° C. to 130 ppm/° C. In some embodiments, the buffer layer 11 may include, or be formed from Ajinomoto build-up film (ABF) or ABF-like material. A dielectric constant (Dk) of the buffer layer 11 may be 3.0 to 3.5. In some embodiments, there may be no electrically conductive path (e.g., circuit layer or conductive layer including traces and/or pads) in the buffer layer 11.

The upper structure 3 is stacked on the buffer layer 11. The upper structure 3 may be an antenna structure, and has a first surface (bottom surface) 31, a second surface (top surface) 32 opposite to the first surface 31 and a lateral side surface 33 extending between the first surface 31 and the second surface 32. The first surface 31 of the upper structure 3 is in contact with the second surface 112 of the buffer layer 11. The upper structure 3 may include at least one upper dielectric layer (including, for example, a first upper dielectric layer 34a and a second upper dielectric layer 34b) and at least one upper metal layer (including, for example, a first upper metal layer 35a, a second upper metal layer 35b and a third upper metal layer 35c) in contact with or interposed between the upper dielectric layers 34a, 34b.

In some embodiments, each of the upper dielectric layers (including, for example, the first upper dielectric layer 34a and the second upper dielectric layer 34b) may include, or be formed from Ajinomoto build-up film (ABF) or ABF-like material. A dielectric constant (Dk) of each of the upper dielectric layers 34a, 34b may be 2.2 to 2.5. Thus, the dielectric constant (Dk) of the lower dielectric layers 24a, 24b, 24c, 24d, 24e is greater than a dielectric constant (Dk) of the upper dielectric layers 34a, 34b.

Each of the upper metal layers 35a, 35b, 35c includes an antenna pattern, and are electrically coupled to one another. In some embodiments, each of the upper metal layers 35a, 35b, 35c does not include a patterned circuit layer (such as a plurality of traces and a plurality of pads), and are not physically connected to one another through any vias. For example, the first upper metal layer 35a is disposed on and attached to the buffer layer 11 and electrically coupled to the fourth lower metal layer 25d of the lower structure 2. The first upper dielectric layer 34a is disposed on and attached to the buffer layer 11 to cover the first upper metal layer 35a. The second upper metal layer 35b is disposed on the first upper dielectric layer 34a and electrically coupled to the first upper metal layer 35a. The second upper dielectric layer 34b is disposed on the first upper dielectric layer 34a to cover the second upper metal layer 35b. The third upper metal layer 35c is disposed on the second upper dielectric layer 34b and electrically coupled to the second upper metal layer 35b.

The lower protection layer 28 (e.g. a solder resist layer) is disposed on the first surface 21 of the lower structure 2 to cover the lower circuit layer 27. The lower protection layer 28 may define a plurality of openings to expose portions of the lower circuit layer 27. In addition, the upper protection layer 29 (e.g. a solder resist layer) is disposed on the second surface 32 of the upper structure 3 to cover the third upper metal layer 35c. In some embodiments, the lower protection layer 28 and the upper protection layer 29 may be omitted.

In the embodiment illustrated in FIG. 1, the CTE of the buffer layer 11 is between the CTE of the lower structure 2 and the CTE of the upper structure 3; thus, a CTE mismatch between the lower structure 2, the buffer layer 11 and the upper structure 3 is gradual; thus, the warpage of the stacked structure 1 is improved. As a result, a delamination between the lower structure 2, the buffer layer 11 and the upper structure 3 may be reduced or avoided, and the yield rate of the stacked structure 1 is improved.

FIG. 2 illustrates a cross-sectional view of a stacked structure 5 according to some embodiments of the present disclosure. The stacked structure 5 includes a lower structure 6, an upper structure 7, a buffer layer 11 and an upper protection layer 29.

The lower structure 6 may be an antenna structure, and has a first surface 61, a second surface 62 opposite to the first surface 61 and a lateral side surface 63 extending between the first surface 61 and the second surface 62. The lower structure 6 may include at least one lower dielectric layer (including, for example, a first lower dielectric layer 64a and a second lower dielectric layer 64b) and at least one lower metal layer (including, for example, a first lower metal layer 65a, a second lower metal layer 65b and a third lower metal layer 65c) in contact with or interposed between the lower dielectric layers 64a, 64b.

In some embodiments, each of the lower dielectric layers (including, for example, the first lower dielectric layer 64a, the second lower dielectric layer 64b and the third lower metal layer 65c) may include, or be formed from Ajinomoto build-up film (ABF) or ABF-like material. A dielectric constant (Dk) of each of the lower dielectric layers 64a, 64b may be 2.2 to 2.5.

Each of the lower metal layers 65a, 65b, 65c includes an antenna pattern, and are electrically coupled to one another. In some embodiments, each of the lower metal layers 65a, 65b, 65c does not include a patterned circuit layer (such as a plurality of traces and a plurality of pads), and are not physically connected to one another through any vias. The first lower dielectric layer 64a covers the first lower metal layer 65a. The second lower metal layer 65b is disposed on the first lower dielectric layer 64a and electrically coupled to the first lower metal layer 65a. The second lower dielectric layer 64b is disposed on the first lower dielectric layer 64a to cover the second lower metal layer 65b. The third lower metal layer 65c is disposed on the second lower dielectric layer 64b and electrically coupled to the second lower metal layer 65b.

The buffer layer 11 is disposed on the lower structure 6, and is interposed between the lower structure 6 and the upper structure 7. The buffer layer 11 has a first surface 111 and a second surface 112 opposite to the first surface 111. The first surface 111 of the buffer layer 11 contacts the second surface 62 of the lower structure 6. A coefficient of thermal expansion (CTE) of the buffer layer 11 is between a coefficient of thermal expansion (CTE) of the lower structure 6 and a coefficient of thermal expansion (CTE) of the upper structure 7. In some embodiments, the CTE of the buffer layer 11 is less than the CTE of the lower structure 6, and is greater than the CTE of the upper structure 7. For example, the CTE of the upper structure 7 may be 9 ppm/° C. to 15 ppm/° C., the CTE of the buffer layer 11 may be 20 ppm/° C. to 50 ppm/° C., and the CTE of the lower structure 6 may be 90 ppm/° C. to 130 ppm/° C.

The upper structure 7 is stacked on the buffer layer 11. The upper structure 7 may be a routing structure, and has a first surface 71, a second surface 72 opposite to the first surface 71 and a lateral side surface 73 extending between the first surface 71 and the second surface 72. The first surface 71 of the upper structure 7 is in contact with the second surface 112 of the buffer layer 11. The upper structure 7 may include at least one lower dielectric layer (including, for example, a first upper dielectric layer 74a, a second upper dielectric layer 74b, a third upper dielectric layer 74c), at least one lower metal layer (including, for example, a first upper metal layer 75a, a second upper metal layer 75b and a third upper metal layer 75c) in contact with or interposed between the upper dielectric layers 74a, 74b, 74c, and a plurality of upper vias (including, for example, a first upper via 76a and a second upper via 76b) embedded in the upper dielectric layers 74a, 74b, 74c.

In some embodiments, each of the upper dielectric layers (including, for example, the first upper dielectric layer 74a, the second upper dielectric layer 74b, the third upper dielectric layer 74c) may include, or be formed from, a photoresist layer, a passivation layer, a cured photo sensitive material, a cured photoimageable dielectric (PID) material such as epoxy, polypropylene (PP), or polyimide (PI) including photoinitiators, or a combination of two or more thereof. A dielectric constant (Dk) of each of the upper dielectric layers 74a, 74b, 74c may be 3.3 to 3.9. Thus, the dielectric constant (Dk) of the lower dielectric layers 64a, 64b is less than a dielectric constant (Dk) of the upper dielectric layers 74a, 74b, 74c. In some embodiments, each of the upper dielectric layers 74a, 74b, 74c may include fibers therein.

Each of the upper metal layers 75a, 75b, 75c includes a patterned circuit layer that may include a plurality of traces and a plurality of pads. The upper metal layers 75a, 75b, 75c are electrically connected to one another through the upper vias (including, for example, the first upper via 76a and the second upper via 76b). For example, the first upper metal layer 75a is disposed on the first upper dielectric layer 74a, and is electrically coupled to the third lower metal layer 65c of the lower structure 6. The second upper dielectric layer 74b is disposed on the first upper dielectric layer 74a to cover the first upper metal layer 75a. The second upper metal layer 75b is disposed on and attached to the second upper dielectric layer 74b and electrically connected to the first upper metal layer 75a through the first upper via 76a. The third upper dielectric layer 74c is disposed on and attached to the second upper dielectric layer 74b to cover the second upper metal layer 75b. The third upper metal layer 75c is disposed on the third upper dielectric layer 74c and electrically connected to the second upper metal layer 75b through the second upper via 76b.

The upper protection layer 29 (e.g. a solder resist layer) is disposed on the second surface 72 of the upper structure 7 to cover the third upper metal layer 75c. The upper protection layer 29 may define a plurality of openings to expose portions of the third upper metal layer 75c. In some embodiments, the upper protection layer 29 may be omitted.

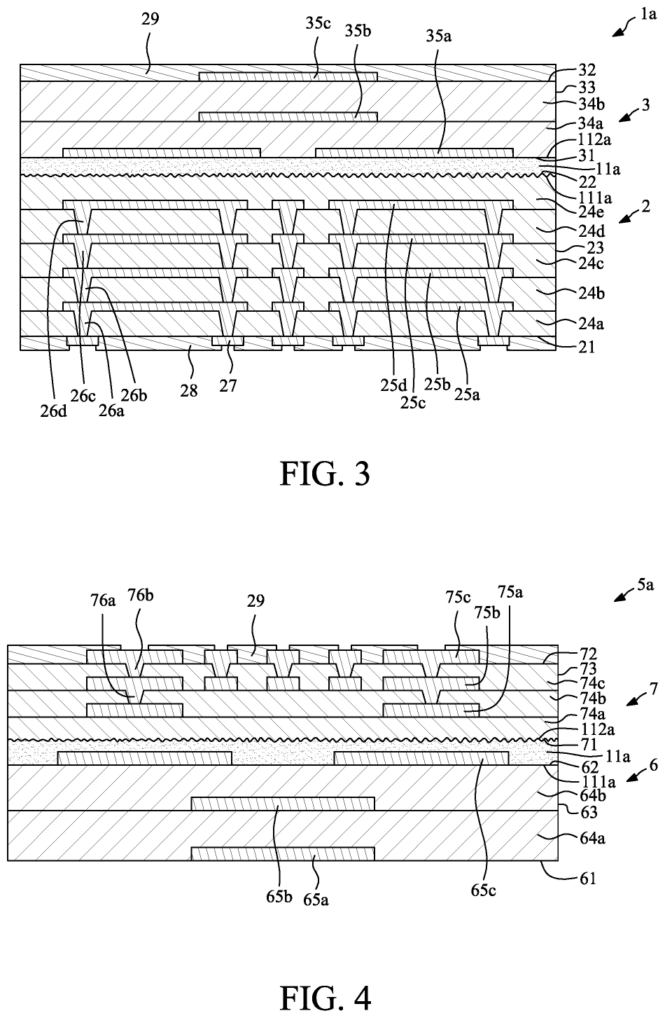

FIG. 3 illustrates a cross-sectional view of a stacked structure 1a according to some embodiments of the present disclosure. The stacked structure 1a is similar to the stacked structure 1 shown in FIG. 1, except for a structure of the buffer layer 11a. The buffer layer 11a has a first surface 111a and a second surface 112a opposite to the first surface 111a. The first surface 111a of the buffer layer 11a is in contact with the second surface 22 of the lower structure 2. The second surface 112a of the buffer layer 11a is in contact with the first surface 31 of the upper structure 3. A surface roughness (Rz) of the first surface 111a of the buffer layer 11a is greater than a surface roughness (Rz) of the second surface 112a of the buffer layer 11a. In some embodiments, the surface roughness (Rz) of the second surface 112a of the buffer layer 11a may be less than 1.5 μm, 1.3 μm or 1.0 μm, and the surface roughness (Rz) of the first surface 111a of the buffer layer 11a may be greater than 2.0 μm and less than 8.0 μm. That is, the surface roughness (Rz) of the first surface 111a of the buffer layer 11a may be greater than 2 times, 3 times, 4 times, or 5 times the surface roughness (Rz) of the second surface 112a of the buffer layer 11a. The rough first surface 111a of the buffer layer 11a may enhance the bonding force or the adhesion force between the buffer layer 11a and the second surface 22 of the lower structure 2. As a result, a delamination between the lower structure 2 and the buffer layer 11a may be reduced or avoided, and the yield rate of the stacked structure 1a is improved.

FIG. 4 illustrates a cross-sectional view of a stacked structure 5a according to some embodiments of the present disclosure. The stacked structure 5a is similar to the stacked structure 5 shown in FIG. 2, except for a structure of the buffer layer 11a. The buffer layer 11a has a first surface 111a and a second surface 112a opposite to the first surface 111a. The first surface 111a of the buffer layer 11a is in contact with the second surface 62 of the lower structure 6. The second surface 112a of the buffer layer 11a is in contact with the first surface 71 of the upper structure 7. A surface roughness (Rz) of the second surface 112a of the buffer layer 11a is greater than a surface roughness (Rz) of the first surface 111a of the buffer layer 11a. In some embodiments, the surface roughness (Rz) of the second surface 112a of the buffer layer 11a may be greater than 2.0 μm and less than 8.0 μm, and the surface roughness (Rz) of the first surface 111a of the buffer layer 11a may be less than 1.5 μm, 1.3 μm or 1.0 μm. That is, the surface roughness (Rz) of the second surface 112a of the buffer layer 11a may be greater than 2 times, 3 times, 4 times, or 5 times the surface roughness (Rz) of the first surface 111a of the buffer layer 11a. The rough second surface 112a of the buffer layer 11a may enhance the bonding force or the adhesion force between the buffer layer 11a and the first surface 71 of the upper structure 7. As a result, a delamination between the upper structure 7 and the buffer layer 11a may be reduced or avoided, and the yield rate of the stacked structure 5a is improved.

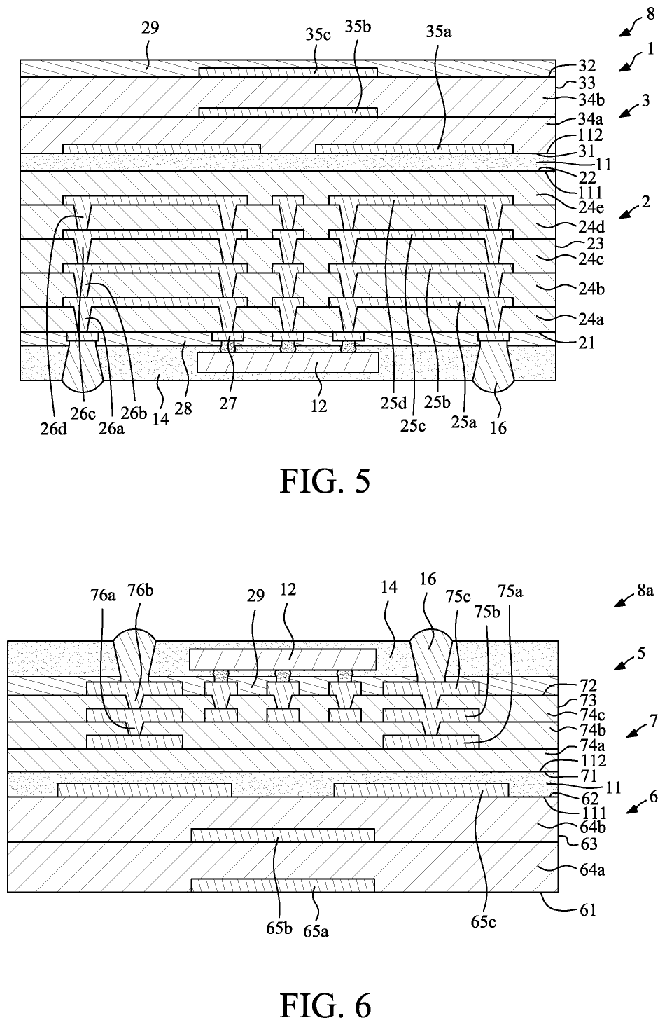

FIG. 5 illustrates a cross-sectional view of a package structure 4 according to some embodiments of the present disclosure. The package structure 4 includes a stacked structure 1, at least one semiconductor die 12, an encapsulant 14 and a plurality of external connectors 16. The stacked structure 1 of FIG. 5 is similar to the stacked structure 1 of FIG. 1. The semiconductor die 12 may be a radio frequency (RF) die, and is electrically connected to the lower circuit layer 27 on the lower structure 2 through a flip-chip bonding. The encapsulant 14 (e.g., a molding compound) covers the semiconductor die 12, and defines a plurality of openings to expose portions of the lower circuit layer 27. The external connectors 16 are disposed in and fill the openings of the encapsulant 14. The external connectors 16 may extend beyond the encapsulant 14 for external connection.

FIG. 6 illustrates a cross-sectional view of a package structure 8a according to some embodiments of the present disclosure. The package structure 8a includes a stacked structure 5, at least one semiconductor die 12, an encapsulant 14 and a plurality of external connectors 16. The stacked structure 5 of FIG. 6 is similar to the stacked structure 5 of FIG. 2. The semiconductor die 12 may be a radio frequency (RF) die, and is electrically connected to the third upper metal layer 75c of the upper structure 7 through a flip-chip bonding. The encapsulant 14 (e.g., a molding compound) covers the semiconductor die 12, and defines a plurality of openings to expose portions of the third upper metal layer 75c. The external connectors 16 are disposed in and fill the openings of the encapsulant 14. The external connectors 16 may extend beyond the encapsulant 14 for external connection.

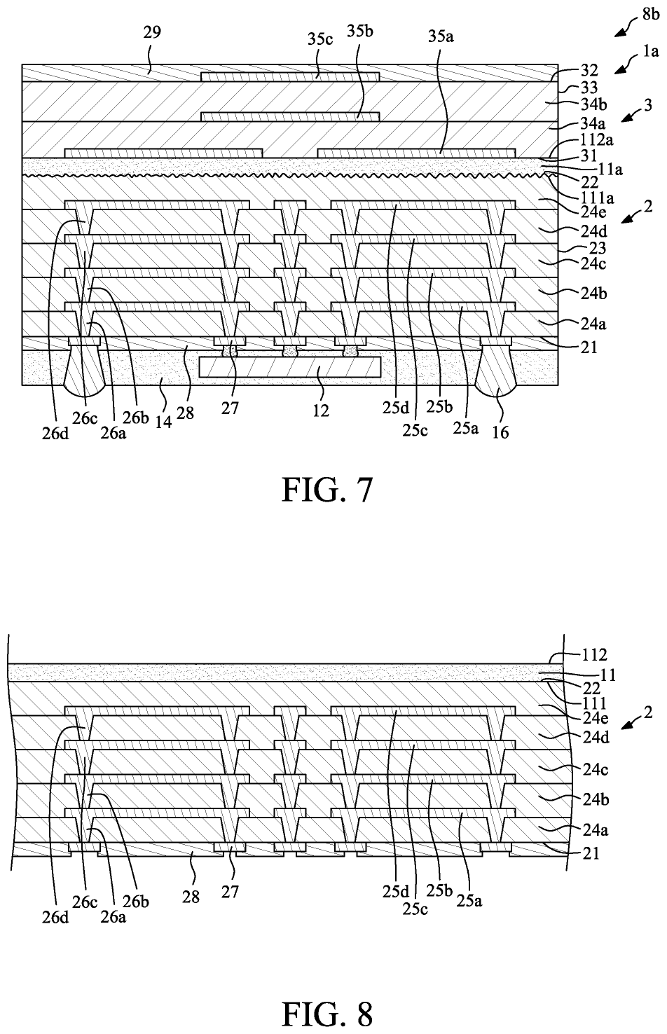

FIG. 7 illustrates a cross-sectional view of a package structure 8b according to some embodiments of the present disclosure. The package structure 8b is similar to the package structure 8 shown in FIG. 5, except for a structure of the stacked structure 1a. In the stacked structure 1a, the buffer layer 11a has a first surface 111a and a second surface 112a opposite to the first surface 111a. The first surface 111a of the buffer layer 11a is in contact with the second surface 22 of the lower structure 2. The second surface 112a of the buffer layer 11a is in contact with the first surface 31 of the upper structure 3. A surface roughness (Rz) of the first surface 111a of the buffer layer 11a is greater than a surface roughness (Rz) of the second surface 112a of the buffer layer 11a. In some embodiments, the surface roughness (Rz) of the second surface 112a of the buffer layer 11a may be less than 1.5 μm, 1.3 μm or 1.0 μm, and the surface roughness (Rz) of the first surface 111a of the buffer layer 11a may be greater than 2.0 μm and less than 8.0 That is, the surface roughness (Rz) of the first surface 111a of the buffer layer 11a may be greater than 2 times, 3 times, 4 times, or 5 times the surface roughness (Rz) of the second surface 112a of the buffer layer 11a.

FIG. 8 through FIG. 10 illustrate a method for manufacturing a stacked structure according to some embodiments of the present disclosure. In some embodiments, the method is for manufacturing the stacked structure 1 shown in FIG. 1.

Referring to FIG. 8, a lower structure 2 is provided or formed. The lower structure 2 may be a routing structure, and has a first surface 21 and a second surface 22 opposite to the first surface 21. The lower structure 2 may include at least one lower dielectric layer (including, for example, a first lower dielectric layer 24a, a second lower dielectric layer 24b, a third lower dielectric layer 24c, a fourth lower dielectric layer 24d and a fifth lower dielectric layer 24e), at least one lower metal layer (including, for example, a first lower metal layer 25a, a second lower metal layer 25b, a third lower metal layer 25c, a fourth lower metal layer 25d) in contact with or interposed between the lower dielectric layers 24a, 24b, 24c, 24d, 24e, and a plurality of lower vias (including, for example, a first lower via 26a, a second lower via 26b, a third lower via 26c and a fourth lower via 26d) embedded in the lower dielectric layers 24a, 24b, 24c, 24d.

Then, a buffer layer 11 is formed or disposed on the lower structure 2. The buffer layer 11 has a first surface 111 and a second surface 112 opposite to the first surface 111. The first surface 111 of the buffer layer 11 contacts the second surface 22 of the lower structure 2.

In some embodiments, before the formation of the buffer layer 11, the top surface (e.g., the second surface 22) of the lower structure 2 (e.g., the top surface of the fifth lower dielectric layer 24e) is roughened by plasma etching or chemical etching. For example, the surface roughness (Rz) of the top surface (e.g., the second surface 22) of the lower structure 2 (e.g., the top surface of the fifth lower dielectric layer 24e) may be greater than 2.0 μm and less than 8.0 μm. The rough top surface of the lower structure 2 may enhance the bonding force or the adhesion force between the buffer layer 11 and the lower structure 2 (as shown in FIG. 3). As a result, a delamination between the lower structure 2 and the buffer layer 11 may be reduced or avoided.

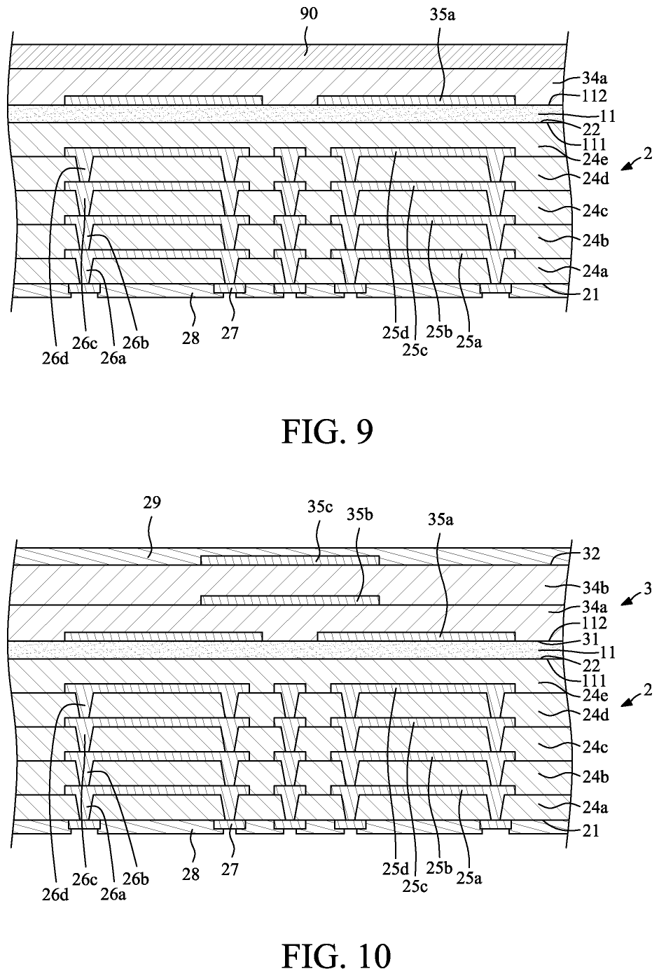

Referring to FIG. 9, a first upper metal layer 35a is formed or disposed on the buffer layer 11. Then, a first upper dielectric layer 34a is formed or disposed on the buffer layer 11 to cover the first upper metal layer 35a. Then, the first upper dielectric layer 34a is conducted by a compression process through a press tool 90. In some embodiments, the press tool 90 may be a solid steel plate or a solid steel stencil. The entire bottom surface of the press tool 90 contacts the entire top surface of the first upper dielectric layer 34a so as to press the whole first upper dielectric layer 34a to the buffer layer 11.

Referring to FIG. 10, the press tool 90 is removed. Then, a second upper metal layer 35b is formed or disposed on the first upper dielectric layer 34a. Then, a second upper dielectric layer 34b is formed or disposed on the first upper dielectric layer 34a to cover the second upper metal layer 35b. Then, a third upper metal layer 35c is formed or disposed on the second upper dielectric layer 34b. Meanwhile, an upper structure 3 is formed. The upper structure 3 may be an antenna structure, and has a first surface 31 and a second surface 32.

Then, an upper protection layer 29 is formed or disposed on the second surface 32 of the upper structure 3 to cover the third upper metal layer 35c. Then, a singulation process is conducted to obtain a plurality of stacked structures 1 of FIG. 1.

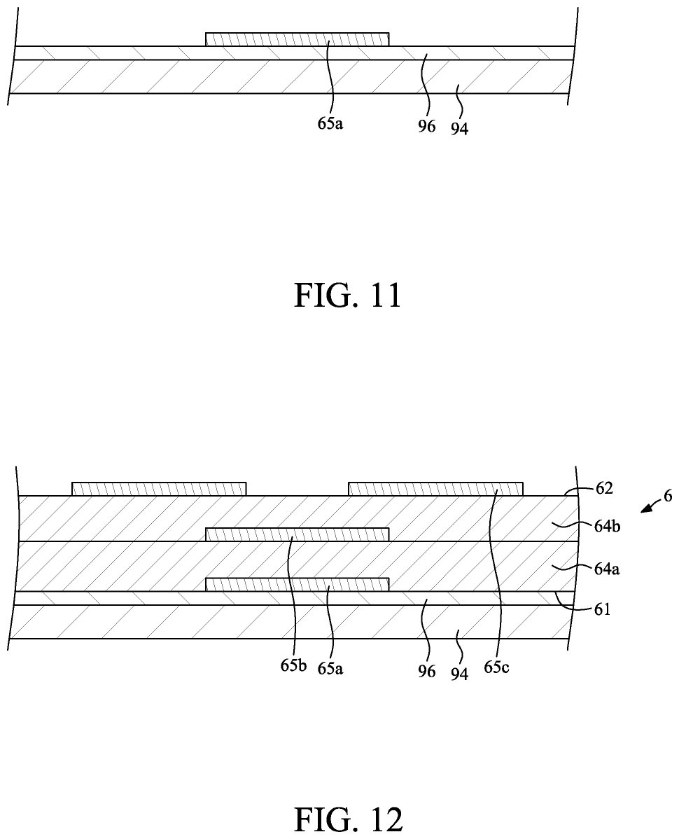

FIG. 11 through FIG. 18 illustrate a method for manufacturing a stacked structure according to some embodiments of the present disclosure. In some embodiments, the method is for manufacturing the stacked structure 5 shown in FIG. 2.

Referring to FIG. 11, a carrier 94 with a release film 96 is provided. Then, a first lower metal layer 65a is formed on the release film 96 on the carrier 94.

Referring to FIG. 12, a first lower dielectric layer 64a is formed or disposed to cover the first lower metal layer 65a. Then, a second lower metal layer 65b is formed or disposed on the first lower dielectric layer 64a. Then, a second lower dielectric layer 64b is formed or disposed on the first lower dielectric layer 64a to cover the second lower metal layer 65b. Then, a third lower metal layer 65c is formed or disposed on the second lower dielectric layer 64b. Meanwhile, a lower structure 6 is formed. The lower structure 6 may be an antenna structure, and has a first surface 61 and a second surface 62.

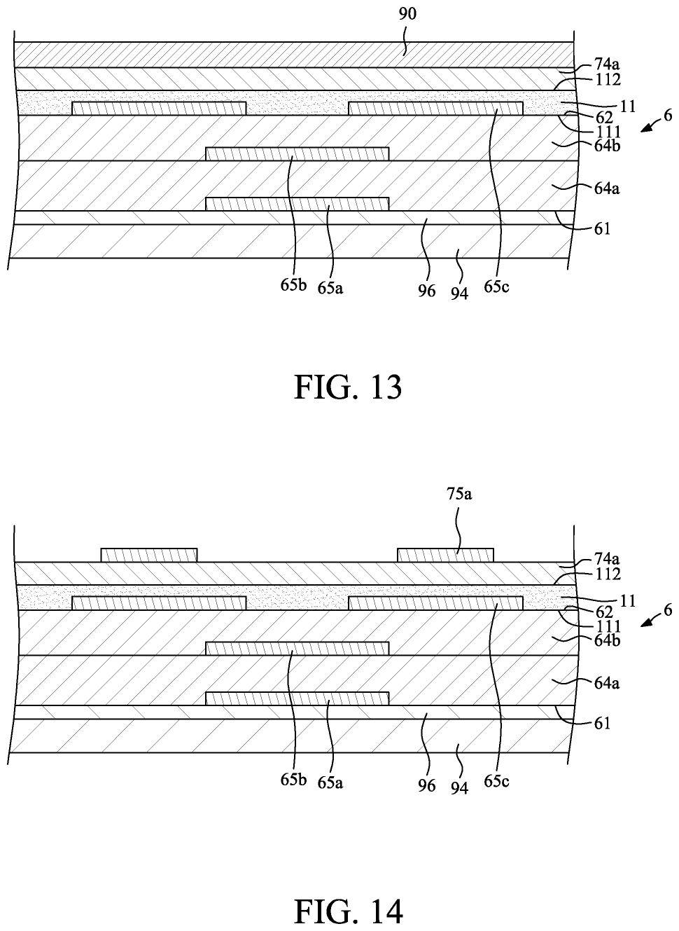

Referring to FIG. 13, a buffer layer 11 is formed or disposed on the lower structure 6 to cover the third lower metal layer 65c. The buffer layer 11 has a first surface 111 and a second surface 112 opposite to the first surface 111. The first surface 111 of the buffer layer 11 contacts the second surface 62 of the lower structure 6. Then, a first upper dielectric layer 74a is formed or disposed on the second surface 112 of the buffer layer 11.

In some embodiments, before the formation of the first upper dielectric layer 74a, the top surface (e.g., the second surface 112) of the buffer layer 11 is roughened by plasma etching or chemical etching. For example, the surface roughness (Rz) of the top surface (e.g., the second surface 112) of the buffer layer 11 may be greater than 2.0 μm and less than 8.0 μm. The rough top surface of the buffer layer 11 may enhance the bonding force or the adhesion force between the buffer layer 11 and the upper structure 7 (as shown in FIG. 4). As a result, a delamination between the upper structure 7 and the buffer layer 11 may be reduced or avoided.

Then, the first upper dielectric layer 74a is conducted by a compression process through a press tool 90. In some embodiments, the press tool 90 may be a solid steel plate or a solid steel stencil. The entire bottom surface of the press tool 90 contacts the entire top surface of the first upper dielectric layer 74a so as to press the whole first upper dielectric layer 74a to the buffer layer 11 and the lower structure 6.

Referring to FIG. 14, the press tool 90 is removed. Then, a first upper metal layer 75a is formed or disposed on the first upper dielectric layer 74a.

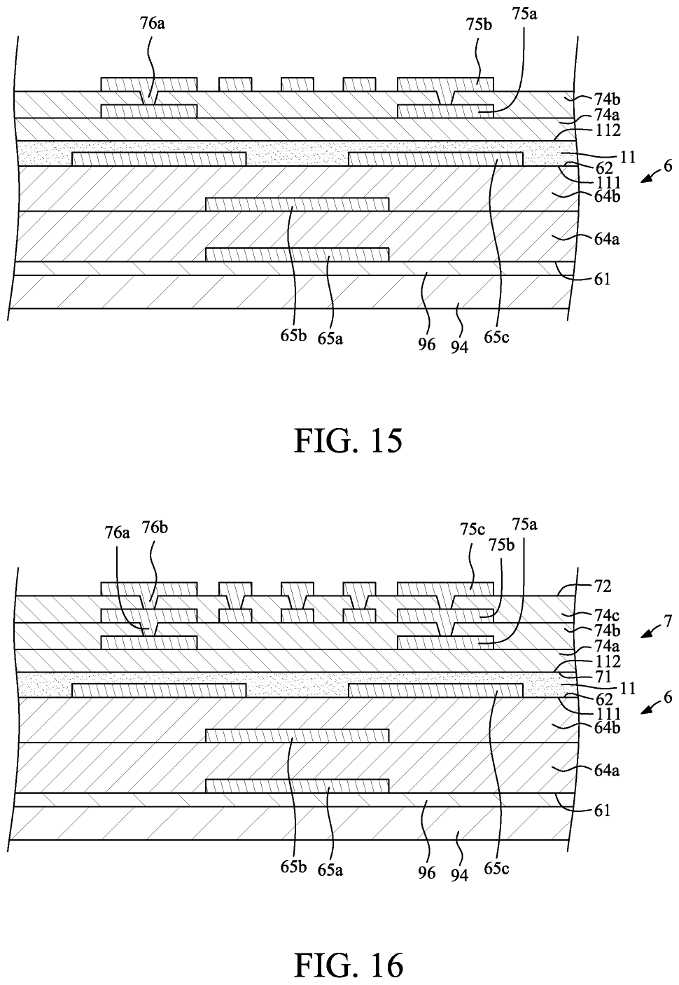

Referring to FIG. 15, a second upper dielectric layer 74b is formed or disposed on the first upper dielectric layer 74a to cover the first upper metal layer 75a. Then, a second upper metal layer 75b is formed or disposed on the second upper dielectric layer 74b.

Referring to FIG. 16, a third upper dielectric layer 74c is formed or disposed on the second upper dielectric layer 74b to cover the second upper metal layer 75b. Then, a third upper metal layer 75c is formed or disposed on the third upper dielectric layer 74c. Meanwhile, an upper structure 7 is formed. The upper structure 7 may be a routing structure, and has a first surface 71 and a second surface 72.

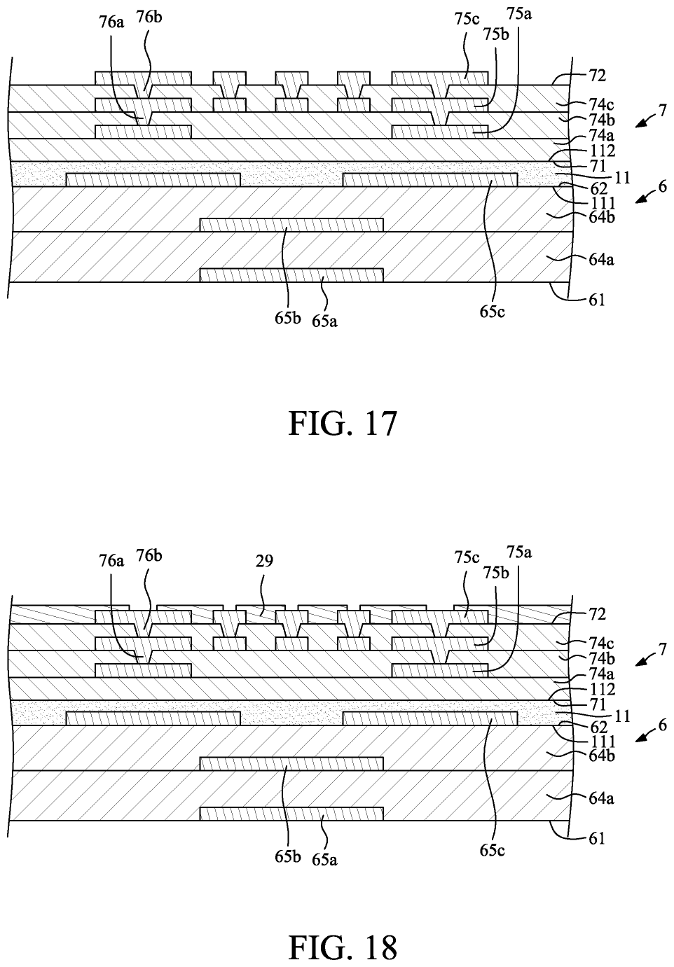

Referring to FIG. 17, the carrier 94 with the release film 96 is removed.

Referring to FIG. 18, an upper protection layer 29 is formed or disposed on the second surface 72 of the upper structure 7 to cover the third upper metal layer 75c. The upper protection layer 29 may define a plurality of openings to expose portions of the third upper metal layer 75c.

Then, a singulation process is conducted to obtain a plurality of stacked structures 5 of FIG. 2.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A stacked structure, comprising:
a lower structure including at least one lower dielectric layer and at least one lower metal layer in contact with the lower dielectric layer;
an upper structure including at least one upper dielectric layer and at least one upper metal layer in contact with the upper dielectric layer; and
a buffer layer interposed between the lower structure and the upper structure, wherein a coefficient of thermal expansion (CTE) of the buffer layer is between a coefficient of thermal expansion (CTE) of the lower structure and a coefficient of thermal expansion (CTE) of the upper structure.

2. The stacked structure of claim 1, wherein the lower structure is a routing structure, and includes a plurality of lower dielectric layers and a plurality of lower metal layers interposed between the lower dielectric layers, each of the lower metal layers includes a patterned circuit layer, the lower metal layers are electrically connected to one another through a plurality of lower vias; wherein the upper structure is an antenna structure, and the at least one upper metal layer includes an antenna pattern.

3. The stacked structure of claim 2, further comprises:
at least one semiconductor die electrically connected to the lower structure; and
an encapsulant covering the at least one semiconductor die.

4. The stacked structure of claim 1, wherein the lower structure is an antenna structure, and the at least one lower metal layer includes an antenna pattern; wherein the upper structure is a routing structure, and includes a plurality of upper dielectric layers and a plurality of upper metal layers interposed between the upper dielectric layers, each of the upper metal layers includes a patterned circuit layer, the upper metal layers are electrically connected to one another through a plurality of upper vias.

5. The stacked structure of claim 4, further comprises:
at least one semiconductor die electrically connected to the upper structure; and
an encapsulant covering the at least one semiconductor die.

6. The stacked structure of claim 1, wherein a dielectric constant (Dk) of the at least one lower dielectric layer is greater than a dielectric constant (Dk) of the at least one upper dielectric layer.

7. The stacked structure of claim 1, wherein a dielectric constant (Dk) of the at least one lower dielectric layer is less than a dielectric constant (Dk) of the at least one upper dielectric layer.

8. The stacked structure of claim 1, wherein a material of the buffer layer includes Ajinomoto build-up film (ABF).

9. The stacked structure of claim 1, wherein there is no electrically conductive path in the buffer layer, wherein a lower metal layer of the lower structure is electrically coupled to the upper structure.

10. A stacked structure, comprising:
a routing structure including at least one dielectric layer and at least one metal layer in contact with the dielectric layer;
an antenna structure including at least one dielectric layer and at least one metal layer in contact with the dielectric layer; and
a buffer layer having a first surface in contact with the routing structure and a second surface opposite to the first surface and in contact with the antenna structure, wherein a surface roughness of the first surface is greater than a surface roughness of the second surface.

11. The stacked structure of claim 10, wherein the routing structure includes a plurality of dielectric layers and a plurality of metal layers interposed between the dielectric layers, each of the metal layers includes a patterned circuit layer, the metal layers are electrically connected to one another through a plurality of lower vias, and the at least one metal layer of the antenna structure includes an antenna pattern.

12. The stacked structure of claim 10, further comprises:
at least one semiconductor die electrically connected to the routing structure; and
an encapsulant covering the at least one semiconductor die.

13. The stacked structure of claim 10, wherein a dielectric constant (Dk) of the at least one dielectric layer of the routing structure is greater than a dielectric constant (Dk) of the at least one dielectric layer of the antenna structure.

14. The stacked structure of claim 10, wherein a material of the buffer layer includes Ajinomoto build-up film (ABF).

15. The stacked structure of claim 10, wherein there is no electrically conductive path in the buffer layer, wherein a metal layer of the routing structure is electrically coupled to the antenna structure.

16. The stacked structure of claim 10, wherein a coefficient of thermal expansion (CTE) of the at least one dielectric layer of the antenna structure is greater than a coefficient of thermal expansion (CTE) of the buffer layer, and the coefficient of thermal expansion (CTE) of the buffer layer is greater than a coefficient of thermal expansion (CTE) of the at least one dielectric layer of the routing structure.

17. The stacked structure of claim 10, wherein the surface roughness of the first surface is greater than 2 μm and less than 8 μm, and the surface roughness of the second surface is less than 1.5 μm.

18. A method for manufacturing a stacked structure, comprising:
(a) forming a lower structure, wherein the lower structure includes at least one lower dielectric layer and at least one lower metal layer in contact with the lower dielectric layer;
(b) forming a buffer layer on the top surface of the lower structure, wherein the buffer layer has a first surface and a second surface opposite to the first surface, the first surface of the buffer layer contacts the top surface of the lower structure, and a surface roughness of the first surface of the buffer layer is different from a surface roughness of the second surface of the buffer layer; and
(c) forming an upper structure on the buffer layer, wherein the upper structure includes at least one upper dielectric layer and at least one upper metal layer in contact with the upper dielectric layer.

19. The method of claim 18, wherein after (a), the method further comprising:
(a1) roughening the top surface of the lower structure.

20. The method of claim 18, wherein after (b), the method further comprising:
(b1) roughening the second surface of the buffer layer.
